(19) United States
(12) Patent Application Publication
(10) Pub. No.: US 2009/0195264 A1
(43) Pub. Date: Aug. 6, 2009

(54) High temperature test system

(75) Inventors: Wen-Yuan Tsen, Nan-Tou Hsien (TW); Guei-Tang Huang, Nan-Tou Hsien (TW); Sung-Rong Shu, Nan-Tou Hsien (TW); Wan-Te Hung, Nan-Tou Hsien (TW); Chih-Wei Lee, Nan-Tou Hsien (TW); Su-Hui Wang, Nan-Tou Hsien (TW); Chih-Hung Huang, Nan-Tou Hsien (TW)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: Universal Scientific Industrial Co., Ltd.

(21) Appl. No.: 12/012,560

(22) Filed: Feb. 4, 2008

(51) Int. Cl. G01R 31/02

(52) U.S. Cl. 324/760

(57) ABSTRACT

A high temperature test system is adapted for testing a device under test (DUT) under a high temperature environment. The high temperature test system includes a preheating unit, a first moving unit, a testing unit, and a second moving unit. The preheating unit is adapted for preheating the DUT. The first moving unit is adapted for removing the preheated DUT from the preheating unit. The testing unit is adapted for placement of the DUT removed by the first moving unit, for testing the DUT, and for providing the high temperature environment to the DUT during testing. The second moving unit is adapted for removing the DUT that has passed testing from the testing unit.

### BACKGROUND OF THE INVENTION

1. Field of the Invention

This invention relates to a test system, more particularly to a high temperature test system for performing a high temperature test in an automated manner.

2. Description of the Related Art

Many integrated circuits (Integrated Circuit, IC) in use today are subjected to harsh environments, including high temperature environments. In a vehicle application, for example, an integrated circuit situated in close proximity to the engine must perform under the high temperatures generated during operation of the vehicle. Integrated circuits in these types of applications must pass a high temperature test in which the test temperature is at least 140° C. in order to ensure normal functioning under high temperature environments.

In a conventional high temperature test, an integrated circuit is gradually heated until it reaches the test temperature, and a testing device is then used to test electrical characteristics of the integrated circuit. The integrated circuit is then classified as either passing or failing. Since the conventional test requires manual movement of the integrated circuit and manual interpretation of the test results, it is time consuming, error prone, and unsafe for operators.

### SUMMARY OF THE INVENTION

Therefore, an object of the present invention is to provide a high temperature test system that is capable of overcoming the aforementioned drawbacks of the prior art.

According to the present invention, there is provided a high temperature test system adapted for testing a device under test (DUT) under a high temperature environment. The high temperature test system comprises a preheating unit, a first moving unit, a testing unit, and a second moving unit.

The preheating unit includes a conveying mechanism adapted for moving the DUT along an advancing direction, and a heating device adapted for preheating the DUT being moved by the conveying mechanism.

The first moving unit is adapted for removing the DUT preheated by the preheating unit from the conveying mechanism.

The testing unit includes a supporting member, a testing member, and a heating element. The supporting member is adapted for placement of the DUT removed by the first moving unit from the conveying mechanism thereon. The testing member is adapted for testing the DUT placed on the supporting member. The heating element is adapted for providing the high temperature environment to the DUT being tested by the testing member.

The second moving unit is adapted for removing the DUT that has passed testing by the testing member from the supporting member of the testing unit.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic diagram of a preferred embodiment of a high temperature test system according to the present invention; and

FIG. 2 is a flow chart of an operational flow of the preferred embodiment.

### DETAILED DESCRIPTION OF THE PREFERRED EMBODIMENT

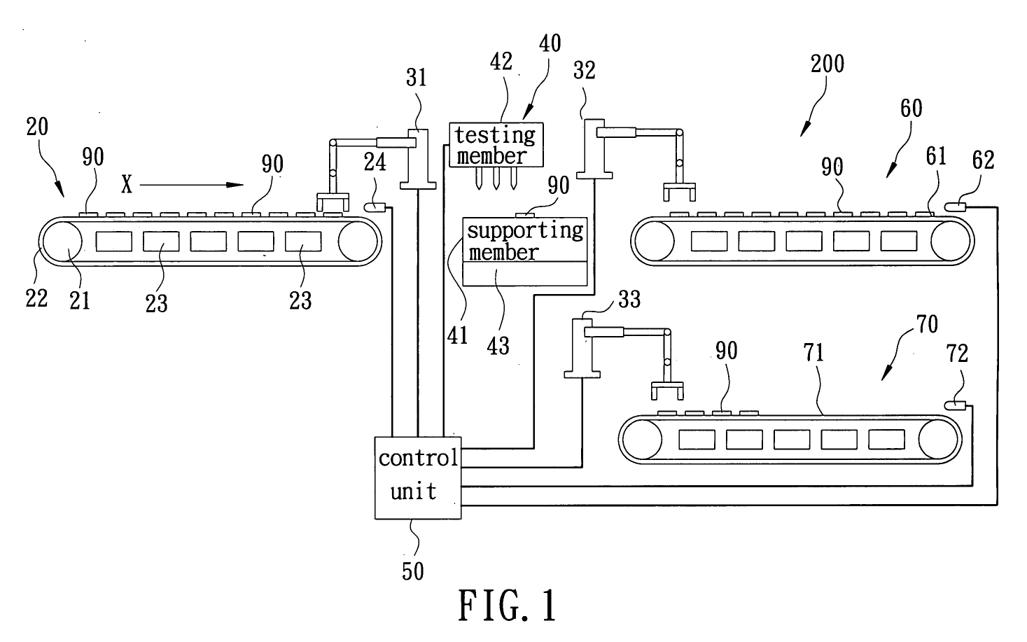

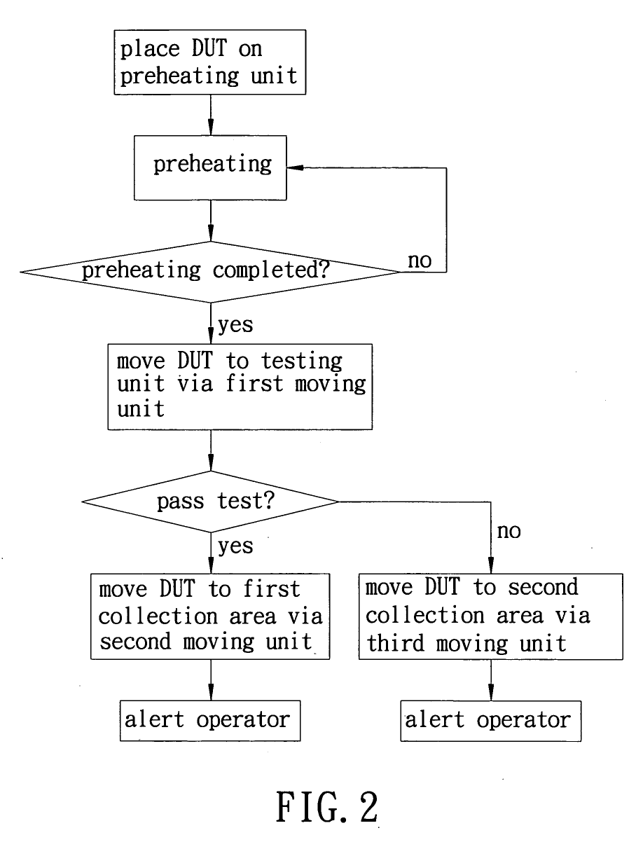

FIGS. 1 and 2 illustrate a preferred embodiment of a high temperature test system 200 adapted for testing a device under test (DUT) 90 under a high temperature environment. The high temperature test system 200 comprises a preheating unit 20, a first moving unit, a testing unit 40, and a second moving unit.

The preheating unit 20 includes a conveying mechanism adapted for moving the DUT 90 along an advancing direction (X), and a heating device adapted for preheating the DUT 90 being moved by the conveying mechanism. In this embodiment, the conveying mechanism includes a drive module 21 and a conveyor belt 22 coupled to and driven by the drive module 21. The DUT 90 is placed on the conveyor belt 21 so as to be moved thereby along the advancing direction (X). Preferably, the heating device includes a plurality of preheating elements 23 that are spaced apart from each other along the advancing direction (X), and that are operated at temperatures which increase along the advancing direction (X) such that the DUT 90 being moved by the conveying mechanism is preheated in a progressive manner. In this embodiment, the preheating elements 23 are operated such that the temperature of the DUT 90 increases from room temperature to 140° C. as the DUT 90 is moved along the advancing direction (X).

The first moving unit is adapted for removing the DUT 90 preheated by the preheating unit 20 from the conveying mechanism. In this embodiment, the first moving unit is a first mechanical arm 31.

Preferably, the high temperature test system 200 is further provided with a sensor 24 adapted for detecting the DUT 90 being conveyed by the conveying mechanism and to be removed therefrom by the first moving unit, which in this embodiment is the first mechanical arm 31. In this embodiment, the sensor 24 is disposed at the conveying mechanism near the preheating element 23 operated at the highest temperature of the heating device of the preheating unit 20, so as to detect the DUT 90 as it completes preheating.

Preferably, the high temperature test system 200 further includes a control unit 50 that is connected electrically to the sensor 24 and the first mechanical arm 31, and that is responsive to output of the sensor 24 for driving operation of the first mechanical arm 31 to remove the DUT 90 from the conveying mechanism.

The testing unit 40 includes a supporting member 41, a testing member 42, and a heating element 43. The supporting member 41 is adapted for placement of the DUT 90 removed by the first mechanical arm 31 from the conveying mechanism thereon. In this embodiment, the DUT 90 remains on the supporting member 41 for a test period of 15 seconds. The testing member 42 is adapted for testing the DUT 90 placed on the supporting member 41. In this embodiment, the testing member 42 is provided with a plurality of probes directed toward the supporting member 41 for testing electrical characteristics of the DUT 90 placed on the supporting member 41. The heating element 43 is adapted for providing the high temperature environment to the DUT 90 being tested by the testing member 42. Preferably, the heating element 43 is operated at a temperature that is not less than a highest temperature of the preheating elements 23 of the heating device of the preheating unit 20. In this embodiment, the heating element 43 is operated to provide a 140° C. environment to the DUT being tested.

The second moving unit is adapted for removing the DUT 90 that has passed testing by the testing member 42 from the supporting member 41 of the testing unit 40. In this embodiment, the second moving unit is a second mechanical arm 32.

Preferably, the control unit 50 is further connected electrically to the testing member 42 and the second moving unit, which in this embodiment is the second mechanical arm 32, and is responsive to output of the testing member 42 at the end of the test period for driving operation of the second mechanical arm 32 to remove the DUT 90 that has passed testing by the testing member 42 from the supporting member 41 of the testing unit 40. Preferably, the control unit 50 is provided with a timer for timing the test period, and in response to the end of the test period and an output of the testing member 42, drives operation of the second mechanical arm 32 when appropriate.

Preferably, the high temperature testing system 200 further includes a third moving unit adapted for removing the DUT 90 that did not pass testing by the testing member 42 from the supporting member 41 of the testing unit 40. In this embodiment, the third moving unit is a third mechanical arm 33.

Preferably, the control unit 50 is further connected electrically to the third moving unit, which in this embodiment is the third mechanical arm 33, and is responsive to output of the testing member 42 at the end of the test period for driving operation of the third mechanical arm 33 to remove the DUT 90 that did not pass testing by the testing member 42 from the supporting member 41 of the testing unit 40.

Preferably, the high temperature test system 200 further includes a first collection area 60 and a second collection area 70. The first collection area 60 includes a first conveyor 61 adapted for advancing the DUT 90 removed by the second mechanical arm 32 from the supporting member 41 of the testing unit 40, and a first detector 62 adapted to generate an output upon detection of the DUT 90 on the first conveyor 61. The second collection area 70 includes a second conveyor 71 adapted for advancing the DUT 90 removed by the third mechanical arm 33 from the supporting member 41 of the testing unit 40, and a second detector 72 adapted to generate an output upon detection of the DUT 90 on the second conveyor 71. In this embodiment, the control unit 50 is further connected electrically to the first and second detectors 62, 72 and is responsive to outputs of the first and second detectors 62, 72 in a manner to be described hereinafter.

In operation of the high temperature test system 200, a DUT 90 is first placed on the preheating unit 20. When preheating is completed, the control unit 50 drives the first mechanical arm 31 to remove the DUT 90 from the preheating unit 20 and to place the DUT 90 on the supporting member 41 of the testing unit 40 for testing. If the DUT 90 passes the test, the control unit 50 drives the second mechanical arm 32 to remove the DUT 90 from the testing unit 40 and to place the DUT 90 on the first collection area 60, and if the DUT 90 fails the test, the control unit 50 drives the third mechanical arm 33 to remove the DUT 90 from the testing unit 40 and to place the DUT on the second collection area 70. The first detector 62, upon detecting a DUT 90 that has passed testing on the first conveyor 61, generates an output to which the control unit 50 responds by issuing a signal that alerts an operator to the presence of the DUT 90 in the first collection area 60. Correspondingly, the second detector 72, upon detecting a DUT 90 that has failed testing on the second conveyor 71, generates an output to which the control unit 50 responds by issuing a signal that alerts the operator to the presence of the DUT 90 in the second collection area 70.

It has thus been shown that the high temperature test system of the present invention automates high temperature testing, thereby increasing efficiency, reducing error, and ensuring operator safety.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A high temperature test system adapted for testing a device under test (DUT) under a high temperature environment, said high temperature test system comprising:
a preheating unit including a conveying mechanism adapted for moving the DUT along an advancing direction, and a heating device adapted for preheating the DUT being moved by said conveying mechanism;
a first moving unit adapted for removing the DUT preheated by said preheating unit from said conveying mechanism;
a testing unit including
a supporting member adapted for placement of the DUT removed by said first moving unit from said conveying mechanism thereon,
a testing member adapted for testing the DUT placed on said supporting member, and
a heating element adapted for providing the high temperature environment to the DUT being tested by said testing member; and
a second moving unit adapted for removing the DUT that has passed testing by said testing member from said supporting member of said testing unit.

2. The high temperature test system as claimed in claim 1, further comprising a third moving unit adapted for removing the DUT that did not pass testing by said testing member from said supporting member of said testing unit.

3. The high temperature test system as claimed in claim 1, wherein said heating device includes a plurality of preheating elements that are spaced apart from each other along the advancing direction.

4. The high temperature test system as claimed in claim 3, wherein said preheating elements of said heating device are operated at temperatures that increase along the advancing direction such that the DUT being moved by said conveying mechanism is preheated in a progressive manner.

5. The high temperature test system as claimed in claim 4, wherein said heating element of said testing unit is operated at a temperature that is not less than a highest temperature of said preheating elements of said heating device of said preheating unit.

6. The high temperature test system as claimed in claim 1, further comprising:
a sensor adapted for detecting the DUT being conveyed by said conveying mechanism and to be removed therefrom by said first moving unit; and
a control unit connected electrically to said sensor and said first moving unit, and responsive to output of said sensor for driving operation of said first moving unit to remove the DUT from said conveying mechanism for placement on said supporting member of said testing unit.

7. The high temperature test system as claimed in claim 6, wherein said control unit is further connected electrically to said testing member and said second moving unit, and is responsive to output of said testing member for driving operation of said second moving unit to remove the DUT that has passed testing by said testing member from said supporting member of said testing unit.

8. The high temperature test system as claimed in claim 2, wherein at least one of said first, second, and third moving units is a mechanical arm.

9. The high temperature test system as claimed in claim 1, further comprising a collection area that includes a conveyor adapted for advancing the DUT removed by said second moving unit from said supporting member of said testing unit, and a detector adapted to generate an output upon detection of the DUT on said conveyor.

10. The high temperature test system as claimed in claim 2, further comprising:
a first collection area that includes a first conveyor adapted for advancing the DUT removed by said second moving unit from said supporting member of said testing unit, and a first detector adapted to generate an output upon detection of the DUT on said first conveyor; and
a second collection area that includes a second conveyor adapted for advancing the DUT removed by said third moving unit from said supporting member of said testing unit, and a second detector adapted to generate an output upon detection of the DUT on said second conveyor.
